(19) United States
(12) Patent Application Publication
(10) Pub. No.: US 2008/0311424 A1
(43) Pub. Date: Dec. 18, 2008

(54) CARBON NANO-TUBE (CNT) THIN FILM COMPRISING AN AMINE COMPOUND, AND A MANUFACTURING METHOD THEREOF

(75) Inventors: Seong Jae Choi, Seoul (KR); Jaeyoung Choi, Suwon-si (KR); Hyeon Jin Shin, Suwon-si (KR); Seonmi Yoon, Yongin-si (KR)

Correspondence Address: CANTOR COLBURN, LLP, 20 Church Street, 22nd Floor, Hartford, CT, 06103, US

(73) Assignee: SAMSUNG ELECTRONICS CO., LTD., Suwon-si (KR)

(21) Appl. No.: 12/034,358

(22) Filed: Feb. 20, 2008

(30) Foreign Application Priority Data
Jun. 12, 2007 (KR) 10-2007-0057236

(51) Int. Cl. H01B 1/04; B32B 27/06; B05D 5/12

(52) U.S. Cl. 428/688; 252/510; 427/77

(57) ABSTRACT

A carbon nano-tube CNT thin film and a manufacturing method thereof are provided. In detail, the CNT thin film comprises a plastic substrate; and a CNT composition being coated over the plastic substrate, in which the CNT composition includes a CNT; and an amine compound of boiling point lower than 150° C. used as a dispersion solvent. When the CNT composition is coated over the plastic substrate, an amine compound is contained in its dispersion liquid. This amine compound is then removed after the CNT composition is coated over the plastic substrate.

This application claims priority to Korean Patent Application No. 10-2007-0057236, filed on Jun. 12, 2007, and all the benefits accruing therefrom under 35 U.S.C. §119, the contents of which are hereby incorporated by reference in its entirety.

### BACKGROUND OF THE INVENTION

The disclosure relates to a carbon nano-tube thin film (hereinafter, referred to as a CNT thin film) and a method of manufacturing the same.

A display device uses a transparent electrode that is optically transparent and electrically conductive. At present, an indium tin oxide (hereinafter abbreviated as ITO) is most commonly used as the transparent electrode. However, the steady increase in ITO consumption has caused an increase in the price thereof. Further, an electrode formed of ITO material tends to cause cracks when it is bent. These cracks lead to an increase in the resistance of the electrode. Thus, this ITO electrode cannot be easily employed in flexible electronic devices such as flexible display devices.

Therefore, it is necessary to develop a transparent electrode material that can be more safely applied to flexible devices. One of the materials that has recently generated interest is a carbon nano-tube (CNT) material. This CNT material has an excellent electro-conductivity and strength while it can be easily bent. Thus, this CNT material can be used to form a flexible transparent electrode, which can be extensively applied to display devices such as conventional LCDs, OLEDs and paper-like displays. Further, it can be used as an electrode material for energy-storage devices such as solar cells and secondary cells.

In case of CNT transparent electrodes, the electroconductivity, transparency and flexibility thereof, among others, are of great importance. In general, CNT transparent electrodes are manufactured by dispersing a CNT powder into a dispersant solution to prepare a CNT ink and by coating or applying the CNT ink on a plastic substrate. In order to improve the electroconductivity of the CNT transparent electrode, it is desirable to ensure that a carrier is able to move within the CNT itself as well as to travel freely between CNTs.

It has been recently discovered that: if a transparent electrode contains a large amount of CNT to make contact with each other, that is, if the amount of CNT is higher than a percolation threshold, the resistance of the CNT network film forming the electrode is governed mostly by the contact resistance between the CNTs, not by the CNT resistance itself.

Therefore, CNT network formation and reduction in the contact resistance between CNTs within the CNT network are useful factors for improving the electroconductivity of a CNT transparent electrode. However, CNTs are initially synthesized in a powder form where numerous CNT bundles are aggregated by van der Waals forces, so the aggregated CNT bundles are to be dispersed individually to form the CNT network.

Development of various dispersants suitable for dispersing CNT has facilitated the formation of a network structure, but the contact resistance between CNTs is rather increased by the resistance of the dispersant itself. Many attempts have been made to solve the problem of contact resistance increase due to the dispersant, including developments of electroconductive dispersants and removal of residual dispersants.

Nevertheless, residual dispersant still causes an increase in the resistance of the entire transparent electrode. Further, dispersant not being adsorbed onto CNT but remaining on the plastic substrate cannot be easily removed. Moreover, most electroconductive polymer dispersants have conjugated chains, so they absorb light in visible-light region, thereby degrading the transmittance thereof.

### SUMMARY OF THE INVENTION

In view of foregoing problems, it is desirable to utilize a short-chain amine compound of low boiling point as a dispersant and solvent, instead of a polymer dispersant or a dispersant having a long alkyl chain, for dispersing CNTs therein, and to manufacture a CNT thin film by applying the CNT containing solution onto a plastic substrate. The short-chain amine having been used as a dispersion solvent is then removed by heating within a temperature range that does not degenerate the plastic substrate, so as to enhance the electroconductivity of an electrode employing the CNT thin film.

In one embodiment, this disclosure is directed to a CNT thin film and a manufacturing method thereof, more specifically, a CNT material and a processing method thereof, capable of increasing the conductivity of a flexible transparent electrode which is manufactured by using a CNT dispersion.

In detail, the CNT thin film comprises a plastic substrate; and a CNT composition being coated over the plastic substrate, in which the CNT composition includes a CNT; and an amine compound of boiling point lower than 150° C. used as a dispersion solvent, wherein the CNT composition contains an amine compound as a dispersion solution when the CNT composition is coated over the plastic substrate, and then the amine compound is removed by heating after the CNT composition is coated over the plastic substrate.

The manufacturing method of a CNT thin film comprises the steps of: preparing a CNT composition by mixing an amine compound of boiling point lower than 150° C. used as a dispersion solvent with a CNT; forming a CNT thin film by coating the CNT composition over a plastic substrate; and removing the amine compound from the CNT thin film by carrying out heat treatment on the CNT thin film.

Accordingly, it is now possible to realize a CNT electrode comprising a CNT thin film with the construction described above, and such a CNT thin film may also be used as a channel material or electrode in thin film transistor (hereinafter abbreviated as ‘TFT’)

### BRIEF DESCRIPTION OF THE DRAWINGS

FIG. 1 diagrammatically shows a process for eliminating an amine compound used as a CNT dispersant through a heat-treatment;

FIG. 2 shows the chemical structures of amine compounds having a boiling point of lower than 150° C.;

FIG. 3 is a photograph showing two kinds of carbon nano-tube (CNT) dispersed solutions, each of which is obtained by dispersing carbon nano-tubes in pyridine and butylamine respectively;

FIG. 4 shows UV-Vis-NIR spectra for CNT-dispersed solutions, which were obtained by dispersing carbon nano-tubes in pyridine, butylamine and N-Methylpyrrolidone (NMP) respectively;

FIG. 5 is a flow chart showing a process for manufacturing a flexible transparent electrode, using different kinds of amine compounds;

FIG. 6 shows decreases in the resistance after a heat treatment at 150° C. for 30 minutes with respect to different CNT thin films where pyridine, butylamine and NMP are used as a dispersant;

FIG. 7 shows decreases in the resistance after a heat treatment at 150° C. for 30 minutes with respect to different CNT thin films manufactured using different kinds of linear alkyl chain amine compounds having different boiling points; and

FIG. 8 shows changes in the resistance after a heat treatment at 150° C. for 30 minutes with respect to different CNT thin films manufactured using as dispersant different kinds of cyclic alkyl chain amine compounds having different boiling points.

### DESCRIPTION OF SPECIFIC EMBODIMENTS

Hereinafter, disclosed embodiments will be set forth in detail with reference to the accompanying drawings.

The terminology used herein is for the purpose of describing particular embodiments only and is not intended to be limiting of the invention. As used herein, the singular forms “a”, “an” and “the” are intended to include the plural forms as well, unless the context clearly indicates otherwise. The use of the terms “first”, “second”, and the like do not imply any particular order but are included to identify individual elements. It will be further understood that the terms “comprises” and/or “comprising”, or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

In the drawings, like reference numerals in the drawings denote like elements and the thicknesses of layer and regions are exaggerated for clarity.

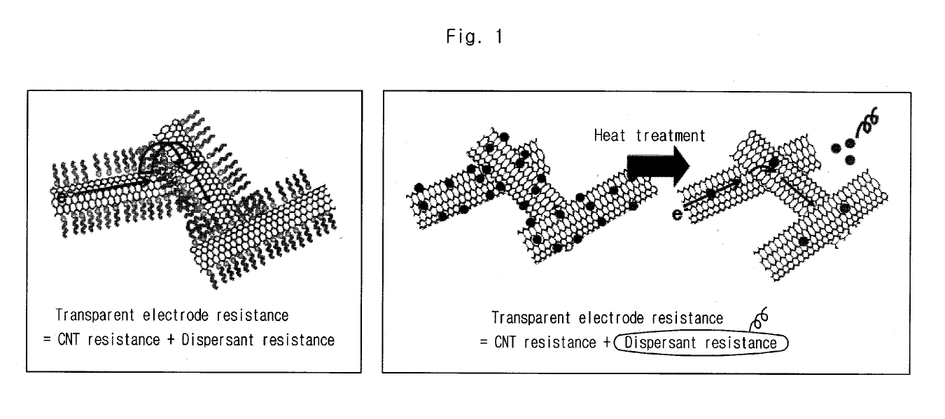

FIG. 1 a diagrammatically shows a process for eliminating an amine compound used as a dispersant according to an embodiment of the present invention. In order to form a CNT network using CNT powder, the CNT powder is to be dispersed in a medium. For this purpose a dispersant is used. However, such a dispersant, by its own resistance, increases the resistance of a transparent electrode formed and thus reduces the electroconductivity of the transparent electrode. In this embodiment, a short-alkyl chain amine compound is employed as a dispersant for a CNT powder. This short-alkyl chain amine compound can easily be removed by heat treatment from the CNT and CNT network.

As shown in FIG. 1, a CNT-dispersed solution is prepared by dispersing a CNT powder in a solvent containing a short-alkyl chain amine compound as a CNT dispersant. The resistance of the amine compound causes an increase in the resistance of the subsequent CNT network. In this embodiment, however, the amine compound containing a short alkyl chain used as a CNT dispersant is eliminated from the CNT-dispersed solution by a heat treatment before manufacturing a transparent electrode using the solution. Thus, the resistance increase caused by the dispersant can be mitigated, and accordingly the resistance of the transparent electrode can be prevented from increasing despite the use of the dispersant.

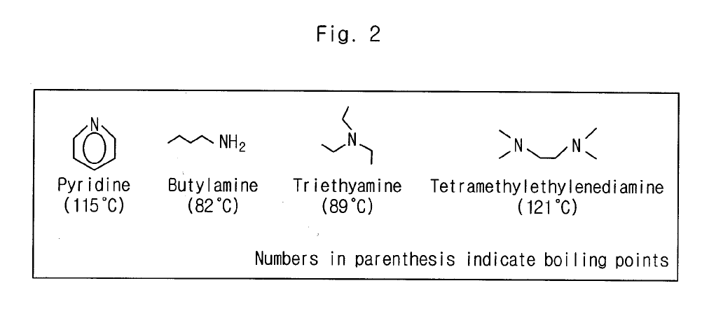

The amine compound has a boiling point of 150° C. or lower and has a short alkyl chain having 3 to 7 carbon atoms. In an embodiment, the amine compound includes a cyclic, linear or branched amine compound containing a short alkyl chain. FIG. 2 shows the chemical structure of amine compounds having a boiling point lower than 150° C. and containing a short alkyl chain. As shown in FIG. 2, pyridine having a boiling point of 115° C. is a cyclic amine compound, butylamine having a boiling point of 82° C. is a linear amine compound, and triethylamine and tetramethylethylenediamine having a boiling point of 89° C. and 121° C. respectively are branched amine compounds.

According to an embodiment, a cyclic, linear, or branched amine compound having a boiling point of lower than 150° C. and containing a short alkyl chain is used as a dispersant or dispersion solvent for preparing a CNT-dispersed solution. It has been found out that an amine compound having a boiling point of lower than 150° C. is more effective to reduce the resistance of a transparent electrode, as compared with an amine compound having a boiling point of higher than 150° C. Detains thereon will be further described hereinafter, in conjunction with the examples.

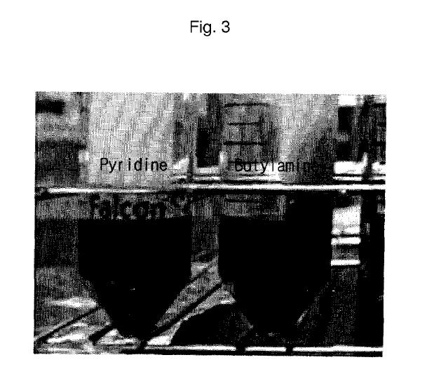

FIG. 3 is a photograph showing two kinds of CNT-dispersed solutions, each of which was obtained by dispersing carbon nano-tubes in pyridine and butylamine respectively according to an embodiment of the present invention. It can be seen in FIG. 3 that the CNTs are well dispersed, without any precipitate in both solutions, even after centrifugation.

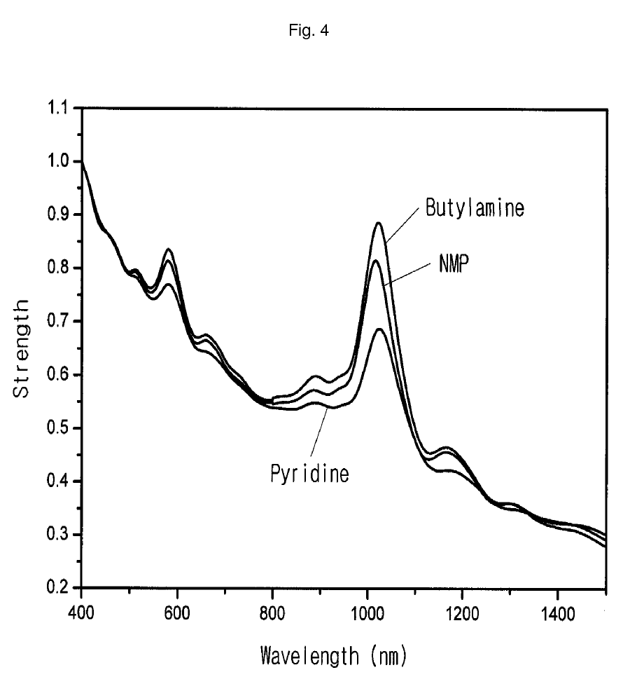

FIG. 4 shows UV-Vis-NIR spectra for CNT-dispersed solutions, which were obtained by dispersing carbon nano-tubes in pyridine, butylamine and n-methylpyrrolidone (NMP) respectively. In FIG. 4, each curve has a similar configuration with peaks in similar positions, which means that there is not much difference in dispersibilities of CNTs dispersed in pyridine, butylamine and NMP respectively.

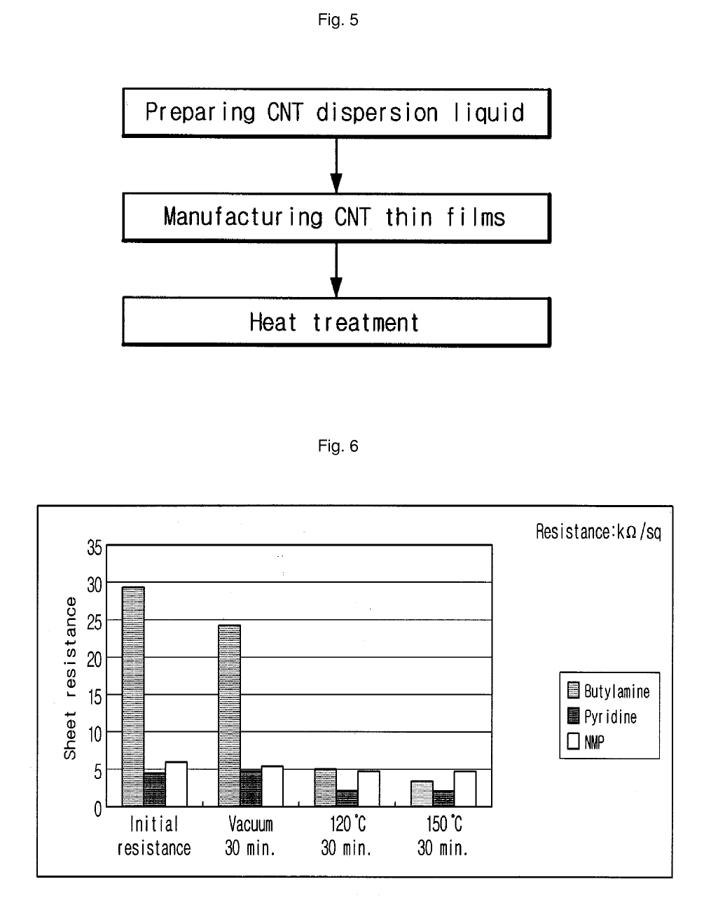

FIG. 5 is a flow chart showing a process for manufacturing a flexible transparent electrode using CNT and different kinds of amine compounds as a dispersant. An experiment has been carried out, using same type of CNTs, the same volume of amine compound, and the same processing time and processing conditions, but all with different kinds of amine compounds.

Hereafter, each step of FIG. 5 will be explained in greater detail, in conjunction with the experiment.

1 mg of single walled CNT (manufactured by SouthWest Nano Technologies, Inc.) was put into several 20 mL glass bottles, and 10 mL of an amine compound was added to each glass bottle. The glass bottles were placed in an ultrasonic bath and treated for 10 hours. Each of the CNT-amine compound solutions was poured into a 50 mL conical tube, and centrifuged for 10 minutes at 10,000 rpm. Following the centrifugation, CNT-dispersed solutions not having produced any precipitate were selected for subsequent processes.

Next, 2 mL of the selected CNT-dispersed amine compound solution was filtered through a vacuum filter onto an aluminum film (Anodisc, 200 nm) to form a CNT thin film. Meanwhile, the CNT thin film formed on the aluminum film can be transferred to other substrate such as a plastic substrate.

Later, the CNT thin film was placed on a hot plate for heat treatment at pre-determined temperatures. In this embodiment, the heating process was performed at temperature of 150° C. or lower in order to protect the surface of the CNT thin film.

The CNT thin film was used for forming a flexible transparent electrode. The resistance of the formed transparent flexible electrode was measured before and after heat-treating at different heat treatment temperatures. It has been found out that the resistance is significantly reduced after heat treatment. This means that the resistance of the transparent electrode has been reduced by eliminating the amine compound through the heat treatment.

The above process for manufacturing a flexible transparent electrode can be summarized as follows.

A CNT-dispersed solution is prepared by dispersing a CNT in a dispersion solvent (dispersant) containing a low-boiling-point amine compound, and the CNT-dispersed solution is coated on a plastic substrate to form a CNT thin film. The CNT thin film is heated to a temperature of 150° C. or lower in order not to damage the plastic substrate where it is coated. By means of this heating, the amine compound used as a dispersant is removed from the CNT thin film, thereby reducing the resistance of the CNT thin film. The resulting CNT thin film may be further heat-treated to further reduce its resistance.

The following examples are not intended to limit the scope of the invention, but provided only for the illustrative purposes.

[Experiment 1]

In Experiment 1, CNTs were dispersed using butylamine and pyridine having a boiling point of lower than 150° C. to prepare CNT-dispersed solutions for Example 1 and Example 2 respectively. CNT thin films were manufactured using the CNT-dispersed solutions. These CNT thin films were heated at 150° C. for 30 minutes to remove the butylamine and pyridine and thus confirm a decrease in the resistance.

For Comparison Example 1, a CNT was dispersed using NMP having a boiling point higher than 150° C. to form a CNT-dispersed solution, which was used to form a CNT thin film. This CNT thin film was also heated at 150° C. for 30 minutes to confirm any decrease in the resistance.

As described above, in Example 1, butylamine, which is a linear alkyl amine compound, was used as an amine compound having a boiling point lower than 150° C. In Example 2, pyridine, which is a cyclic amine compound, was used as an amine compound having a boiling point lower than 150° C. In Comparison Example 1, NMP having a boiling point higher than 150° C. was used. Resistance of the CNT thin films obtained in Experiment 1 was measured and summarized as follows.

### EXAMPLE 1

### Butylamine (b.p.: 82° C.)

Initial resistance: 29.4 kΩ/sq/Resistance in vacuum: 24.4 kΩ/sq/Resistance after heat treatment at 120° C.: 4.99 kΩ/sq /Resistance after heat treatment at 150° C.: 3.26 kΩ/sq.

### EXAMPLE 2

### Pyridine (b.p.: 115° C.)

Initial resistance: 4.3 kΩ/sq/Resistance in vacuum: 4.6 kΩ/sq/Resistance after heat treatment at 120° C.: 2.05 kΩ/sq/Resistance after heat treatment at 150° C.: 1.95 kΩ/sq.

### COMPARISON EXAMPLE 1

### NMP (b.p.: 200° C.)

Initial resistance: 5.86 kΩ/sq/Resistance in vacuum: 5.31 kΩ/sq/Resistance after heat treatment at 120° C.: 4.74 kΩ/sq/Resistance after heat treatment at 150° C.: 4.63 kΩ/sq.

Table 1 shows decrease rates of the resistance obtained from Experiment 1.

TABLE 1

| | | | | | | Decrease rate of |
|---|---|---|---|---|---|---|
| | | | | | | resistance |
| | b.p. | Initial | Vacuum | 120° C. | 150° C. | compared with |
| | (° C.) | resistance | 30 min. | 30 min. | 30 min. | initial resistance |
| Ex. 1 | 82 | 29.4 | 24.4 | 4.99 | 3.26 | −88.9% |
| Ex. 2 | 115 | 4.3 | 4.6 | 2.05 | 1.95 | −54.7% |
| Co. | 200 | 5.86 | 5.31 | 4.74 | 4.63 | −21.0% |
| Ex. 1 | | | | | | |

As shown in Table 1, in the Example 1 where butylamine, a linear alkyl amine compound, was used as a dispersant, the resistance is found out to have been decreased by 88.9% only after the 30 minute-heat treatment at 150° C., as compared with the initial resistance. Likewise, in Example 2 where pyridine, a cyclic amine compound, was used as a dispersant, the resistance is found out to have been decreased by 54.7% after the 30 minute-heat treatment at 150° C., relative to the initial resistance.

From the results of the experiment 1, it can be seen that butylamine, which is a linear alkyl amine compound used in Example 1, is more easily removed by heating, rather than pyridine, which is a cyclic amine compound used in Example 2.

Further, in Comparison Example 1 where NMP having a boiling point higher than 150° C., the decrease rates in the resistance is much lower than in Example 1 and Example 2, where dispersants having a boiling point lower than 150° C. It can be assumed from this result that dispersants having a boiling point lower than 150° C. are more efficient and suitable for decreasing the resistance of final products.

[Experiment 2]

In Experiment 2, CNTs were dispersed respectively in linear alkyl amine compounds having different alkyl chain lengths to prepare CNT-dispersed solutions for Example 3 and Comparison Examples 2 and 3. CNT thin films were manufactured using the CNT-dispersed solutions. These CNT thin films were heated at 150° C. for 30 minutes to confirm changes in the resistance.

All the Examples used linear alkyl amine compounds, but having different alkyl chain lengths. That is, in Example 3, butylamine having a short alkyl chain was used as a linear alkyl amine compound dispersant. Hexylamine and octylamine were used as a linear alkyl amine compound dispersant for Comparison Examples 2 and 3 respectively.

Resistance of the CNT thin films obtained in Experiment 2 was measured and summarized as follows.

### EXAMPLE 3

### Butylamine (b.p.: 82° C.)

Initial resistance: 29.4 kΩ/sq/Resistance in vacuum: 24.4 kΩ/sq/Resistance after heat treatment at 120° C.: 4.99 kΩ/sq/Resistance after heat treatment at 150° C.: 3.26 kΩ/sq.

### COMPARISON EXAMPLE 2

### Hexylamine (b.p.: 131-132° C.)

Initial resistance: 15.4 kΩ/sq/Resistance in vacuum: 13.2 kΩ/sq/Resistance after heat treatment at 120° C.: 9.7 kΩ/sq/Resistance after heat treatment at 150° C.: 8.9 kΩ/sq.

### COMPARISON EXAMPLE 3

### Octylamine (b.p.: 175-177° C.)

Initial resistance: 13.9 kΩ/sq/Resistance in vacuum: 12.8 kΩ/sq/Resistance after heat treatment at 120° C.: 11 kΩ/sq/Resistance after heat treatment at 150° C.: 9.51 kΩ/sq.

Table 2 shows decrease rates of the resistance obtained from Experiment 2.

TABLE 2

| | | | | | | Decrease rate of |
|---|---|---|---|---|---|---|
| | | Initial | | | | resistance |
| | b.p. | resis- | Vacuum | 120° C. | 150° C. | compared with |
| | (° C.) | tance | 30 min. | 30 min. | 30 min. | initial resistance |
| Ex. 3 | 82 | 29.4 | 24.4 | 4.99 | 3.26 | −88.9% |
| Co. | 131-132 | 15.4 | 13.2 | 9.7 | 8.9 | −42.2% |
| Ex. 2 | | | | | | |
| Co. | 175-177 | 13.9 | 12.8 | 11 | 9.51 | −31.6% |
| Ex. 3 | | | | | | |

As shown in Table 2, in Example 3 where butylamine was used as a dispersant, the resistance was decreased by 88.9% only after the 30 minute-heat treatment at 150° C., as compared with the initial resistance. In Comparison Examples 2 and 3 where hexylamine and octylamine were used as dispersants, the resistance was decreased by 42.2% and 31.6% respectively.

From the results of the Experiment 2, it can be seen that Example 3 employing butylamine having a relatively short alkyl chain exhibits a higher decrease rates in the resistance, as compared with Comparison Example 2 and Comparison Example 3 using hexylamine and octylamine having relatively long alkyl chain lengths. This means that an amine compound with a short alkyl chain length can be more easily removed by heating, i.e., is more efficient in reducing the resistance of final products.

[Experiment 3]

In Experiment 3, CNTs were dispersed in cyclic alkyl amine compounds having different boiling points to prepare CNT-dispersed solutions for Example 4 and Comparison Examples 4 to 7 respectively. CNT thin films were manufactured using the CNT-dispersed solutions. These CNT thin films were heated at 150° C. for 30 minutes to confirm changes in the resistance.

All Examples used an amine compound of boiling point lower than 150° C. Specifically, Example 4 used pyridine, a cyclic amine compound, and Comparison Examples 4 and 5 used pyrazine and pyrrole respectively. Comparison Examples 6 and 7 respectively used methylpyridine and ethylpyridine, which are cyclic amine compounds having an alkyl group.

Resistance of the CNT thin films obtained in Experiment 3 was measured and summarized as follows.

### EXAMPLE 4

### Pyridine (b.p.: 115° C.)

Initial resistance: 4.3 kΩ/sq/Resistance in vacuum: 4.6 kΩ/sq/Resistance after heat treatment at 120° C.: 2.05 kΩ/sq/Resistance after heat treatment at 150° C.: 1.95 kΩ/sq.

### COMPARISON EXAMPLE 4

### Pyrazine (b.p.: 115-116° C.)

Initial resistance: 5.9 kΩ/sq/Resistance in vacuum: 5.2 kΩ/sq/Resistance after heat treatment at 120° C.: 3.7 kΩ/sq/Resistance after heat treatment at 150° C.: 3.5 kΩ/sq.

### COMPARISON EXAMPLE 5

### Pyrrole (b.p.: 131° C.)

Initial resistance: 6.1 kΩ/sq/Resistance in vacuum: 5.8 kΩ/sq/Resistance after heat treatment at 120° C.: 4.9 kΩ/sq/Resistance after heat treatment at 150° C.: 4.22 kΩ/sq.

### COMPARISON EXAMPLE 6

### Methylpyridine (b.p.: 145° C.)

Initial resistance: 5.1 kΩ/sq/Resistance in vacuum: 4.8 kΩ/sq/Resistance after heat treatment at 120° C.: 4.31 kΩ/sq/Resistance after heat treatment at 150° C.: 3.6 kΩ/sq.

### COMPARISON EXAMPLE 7

### Ethylpyridine (b.p.: 168° C.)

Initial resistance: 5.4 kΩ/sq/Resistance in vacuum: 5.5 kΩ/sq/Resistance after heat treatment at 120° C.: 4.4 kΩ/sq/Resistance after heat treatment at 150° C.: 4.1 kΩ/sq.

Table 3 shows decrease rates of the resistance obtained from Experiment 3.

TABLE 3

| | | | | | | Decrease rate |
|---|---|---|---|---|---|---|
| | | | | | | of resistance |
| | | Initial | | | | compared |
| | b.p. | resis- | Vacuum | 120° C. | 150° C. | with initial |
| | (° C.) | tance | 30 min. | 30 min. | 30 min. | resistance |
| Ex. 4 | 115 | 4.3 | 4.6 | 2.05 | 1.95 | −54.7% |
| Co. Ex. 4 | 115-116 | 5.9 | 5.2 | 3.7 | 3.5 | −40.7% |
| Co. Ex. 5 | 131 | 6.1 | 5.8 | 4.9 | 4.22 | −30.8% |
| Co. Ex. 6 | 145 | 5.1 | 4.8 | 4.31 | 3.6 | −29.4% |
| Co. Ex. 7 | 168 | 5.4 | 5.5 | 4.4 | 4.1 | −24.1% |

As shown in Table 3, in Example 4 where pyridine was used as a dispersant, the resistance was decreased by 54.7% after the 30 minute-heat treatment at 150° C., as compared with the initial resistance. In Comparison Examples 4 and 5 where pyrazine and pyrrole were used as dispersants, the resistance was decreased by 40.7% and 30.8% respectively, as compared with their initial resistances. In Comparison Examples 6 and 7 where methylpyridine and ethylpyridine were used as dispersants, the resistance was decreased by 29.4% and 24.1% respectively, as compared with their initial resistances.

From the results of the Experiment 3, it can be seen that a cyclic amine compound not having an alkyl group, such as pyridine used in Example 4, is more easily removed by heating, rather than a cyclic amine compound having an alkyl group such as methylpyridine and ethylpyridine used in Comparison Examples 6 and 7.

The results of the Experiments 1 to 3 are further explained and confirmed hereafter.

FIG. 6 is a graph showing decreases in the resistance after a heat treatment for 30 minutes at 150° C. with respect to different CNT thin films manufactured using as a dispersant pyridine, butylamine, and NMP respectively. Referring to FIG. 6 and Example 1, the resistance of the short linear alkyl amine compound such as butylamine has been reduced most remarkably, as compared with the initial resistance thereof. Further, it can be seen from FIG. 6 and Comparison Example 1 that NMP having a boiling point higher than 150° C. did not cause any substantial change in the resistance.

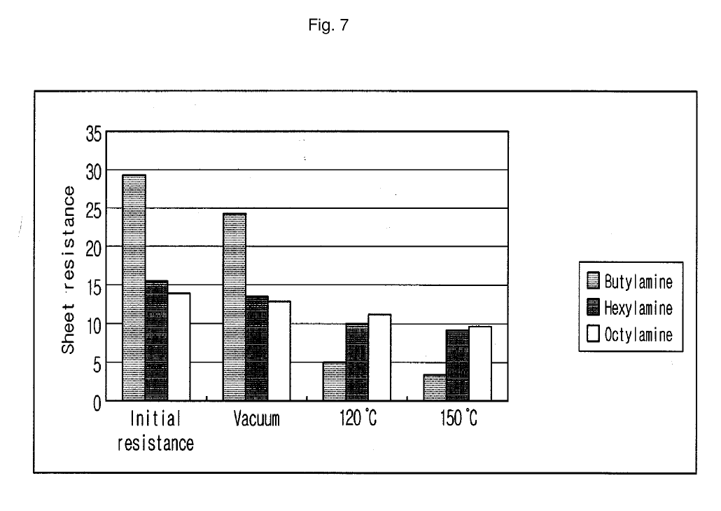

FIG. 7 is a graph showing changes in the resistance after a heat treatment at 150° C. for 30 minutes with respect to different CNT thin films manufactured using as a dispersant different kinds of linear alkyl amine compounds having different boiling points. Referring to FIG. 7 and Example 2, it can be seen that butylamine having the shorter length of the alkyl chain is more efficient in reducing the resistance.

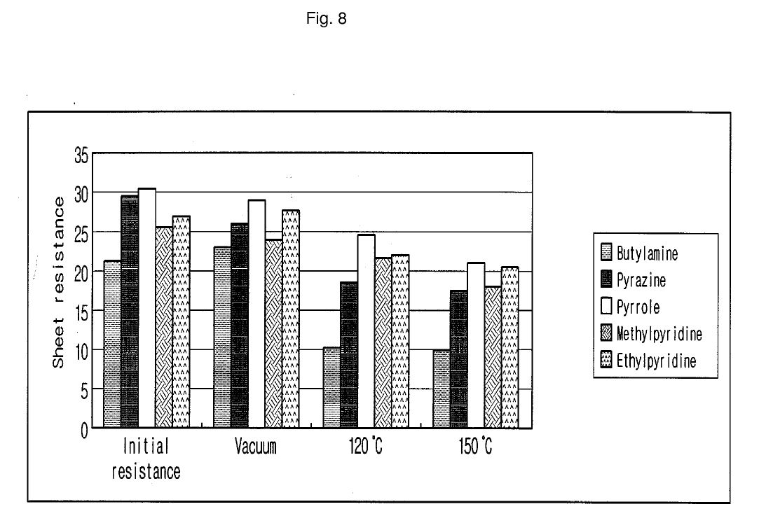

FIG. 8 is a graph showing changes in the resistance after a heat treatment at 150° C. for 30 minutes with respect to different CNT thin films manufactured using as a dispersant different kinds of cyclic alkyl amine compounds having different boiling points. Referring to FIG. 8 and Example 4, it can be seen that cyclic amine compound not having an alkyl group such as pyridine is more effective in decreasing the resistance, as compared with cyclic amine compound having an alkyl group such as methylpyridine of Comparison Example 6 and ethylpyridine of Comparison Example 7.

The above-described examples and results therefrom are summarized as follows.

CNT-dispersed solutions were prepared by dispersing CNTs in dispersion solvents (dispersants) containing short chain amine compounds. It was checked as to whether CNTs were well dispersed in the dispersion solvents without leaving any precipitates after centrifugation. In addition, UV spectrum analysis was performed to confirm as to whether uniform dispersibilities of CNTs can be achieved. A transparent electrode was manufactured using the CNT-amine dispersion solution, and the amine compound was eliminated through heat treatment. Without the amine compound, resistance of the transparent electrode was decreased. For example, in case where butyl amine was used, the resistance was decreased by about 89% only after a 30 minute-heat treatment at 150° C. Similarly, pyridine, a cyclic amine compound, has showed about 55% decrease in the resistance after a 30 minute-heat treatment at 150° C.

A short chain amine compound can be used as a dispersion solvent for dispersing CNT to form CNT-dispersed solution, and the CNT-dispersed solution is coated over a plastic substrate to form a CNT thin film for an electrode. As the dispersion solvent is removed from the CNT thin film through heating, contact resistance between CNTs caused by the dispersant is reduced and thus electroconductivity of the electrode can be improved.

The CNT thin film can be utilized for manufacturing flexible transparent electrodes. Such a CNT thin film can also be used as a channel material or electrode in TFTs.

Further, this technology can be applied to various electronic devices.

While the present invention has been described with respect to the several embodiments, it will be apparent to those skilled in the art that various changes and modifications may be made without departing from the spirit and scope of the invention as defined by the appended claims.

In addition, many modifications can be made to adapt a particular situation or material to the teachings of the invention without departing from the essential scope thereof. Therefore, it is intended that the invention not be limited to the particular embodiments disclosed as the best mode contemplated for carrying out this invention, but that the invention will include all embodiments falling within the scope of the appended claims. Moreover, the use of the terms first, second, etc. do not denote any order or importance, but rather the terms first, second, etc. are used to distinguished one element from another. Furthermore, the use of the terms a, an, etc. do not denote a limitation of quantity, but rather denote the presence of at least one of the referenced item.

What is claimed is:

1. A carbon nano-tube (CNT) composition, comprising:
a CNT; and
a dispersant capable of being removed from the composition through a heat-treatment.

2. The CNT composition of claim 1, wherein the dispersant includes an amine compound.

3. The CNT composition of claim 2, wherein the amine compound has a boiling point of 150° C. or lower.

4. The CNT composition of claim 2, wherein the amine compound includes a cyclic, linear or branched amine compound.

5. The CNT composition of claim 2, wherein the amine compound has an alkyl chain having 3 to 7 carbon atoms.

6. The CNT composition of claim 4, wherein the amine compound selected from the group consisting of butylamine, hexylamine, octylamine, pyridine, pyrazine, pyrrole, methylpyridine, ethylpyridine, n-methylpyrrolidone, and a combination comprising at least one of the foregoing cyclic amine compounds.

7. The CNT composition of claim 1, wherein the heat treatment is carried out at a temperature of 150° C. or lower.

8. A CNT thin film, comprising:
a substrate; and
a CNT composition disposed on the substrate, the CNT composition comprising a CNT and a dispersant capable of being removed from the CNT composition through a heat-treatment.

9. The CNT thin film of claim 8, wherein the substrate is a flexible transparent substrate.

10. The CNT thin film of claim 9, wherein the flexible transparent substrate includes a transparent plastic substrate.

11. The CNT thin film of claim 8, wherein the dispersant includes an amine compound.

12. The CNT thin film of claim 11, wherein the amine compound has a boiling point of 150° C. or lower.

13. The CNT thin film of claim 12, wherein the amine compound includes a cyclic, linear or branched amine compound.

14. The CNT thin film of claim 12, wherein the amine compound selected from the group consisting of butylamine, hexylamine, octylamine, pyridine, pyrazine, pyrrole, methylpyridine, ethylpyridine, n-methylpyrrolidone, and a combination comprising at least one of the foregoing cyclic amine compounds.

15. The CNT thin film of claim 8, wherein the heat treatment is carried out at a temperature of 150° C. or lower.

16. The CNT composition of claim 12, wherein the amine compound has an alkyl chain having 3 to 7 carbon atoms.

17. A method of manufacturing a CNT thin film, comprising the steps of:
mixing CNTs and a dispersant capable of being removed through a heat-treatment to form a CNT dispersed solution;;
forming a CNT thin film by coating the CNT-dispersed solution on a plastic substrate; and
heating the CNT-dispersed solution.

18. The method of claim 17, wherein the dispersant includes an amine compound.

19. The method of claim 18, wherein the amine compound has a boiling point of 150° C. or lower.

20. The method of claim 18, wherein the amine compound selected from the group consisting of butylamine, hexylamine, octylamine, pyridine, pyrazine, pyrrole, methylpyridine, ethylpyridine, n-methylpyrrolidone, and a combination comprising at least one of the foregoing cyclic amine compounds.

21. The method of claim 17, wherein the substrate includes a flexible transparent substrate.

22. The method of claim 21, wherein the flexible transparent substrate includes a plastic substrate.

23. The method of claim 17, wherein in the step of removing the dispersant, the heating is carried out at a temperature of 150° C. or lower.

24. A CNT electrode comprising a CNT thin film according to claim 17.

25. A thin film transistor comprising a CNT thin film according to claim 17.
